(19) United States
(12) Patent Application Publication
(10) Pub. No.: US 2026/0252772 A1
(43) Pub. Date: Aug. 27, 2026

(54) Programmable Matrix Switch Array for Reconfigurable Circuits

(71) Applicant: Board of Regents, The University of Texas System, Austin, TX (US)

(72) Inventors: David Zubia, El Paso, TX (US); Cesar Y. Sanchez-Zambrano, El Paso, TX (US)

(21) Appl. No.: 19/550,404

(22) Filed: Feb. 26, 2026

Related U.S. Application Data
(60) Provisional application No. 63/764,038, filed on Feb. 27, 2025.

(51) Int. Cl. G06F 30/323; G06F 30/343

(52) U.S. Cl. CPC G06F 30/323; G06F 30/343

(57) ABSTRACT

A system includes a programmable matrix switch array including a plurality of cross-point switches arranged in a grid. Each cross-point switch is selectively configurable to establish or break electrical connections at designated intersections of conducting lines. The system includes one or more modular component cards and instrument modules, each removably connected to the programmable matrix switch array. The system includes a configuration module configured to track electronic components mounted on the modular component cards, instrument modules and connections with ports of the programmable matrix switch array and in response generate a portlist. The system includes a programming module configured to interpret a netlist and the portlist and in response generate switch activation commands to selectively control the cross-point switches.

### CROSS-REFERENCE TO RELATED APPLICATION

This application claims the benefit of U.S. Provisional Patent Application Ser. No. 63/764,038, filed Feb. 27, 2025, and entitled “Programmable Matrix Switch Array for Reconfigurable Circuits,” which is incorporated herein by reference in its entirety.

### BACKGROUND INFORMATION

### 1. Field

The present disclosure relates generally to circuits and systems, and more specifically to a programmable matrix switch array for reconfigurable circuits.

### 2. Background

The development of electronic systems often requires rapid prototyping of circuit designs. This process involves interconnecting electronic components in various configurations to evaluate their performance. Traditional prototyping methods rely on physically wiring components together, which is both time-consuming and error-prone. As circuit complexity increases, the number of possible interconnections grows hyper-exponentially, further complicating the prototyping process.

One of the earliest solutions to this problem was the breadboard, which allows for reusable, solderless prototyping. However, breadboards require manual interconnections, limiting their efficiency and scalability. Other prototyping methods provide pre-configured connections that restrict the range of possible circuit topologies.

Modern electronic components, especially those utilizing surface mount technology (SMT), present additional challenges. SMT components lack the through-hole pins required for breadboard use, making manual wiring more difficult. This limitation increases the time and cost associated with prototyping circuits that use SMT components.

### SUMMARY

According to an illustrative embodiment, a system comprises a programmable matrix switch array including a plurality of cross-point switches arranged in a grid. Each cross-point switch is selectively configurable to establish or break electrical connections at designated intersections of conducting lines. The system comprises one or more modular component cards, each removably connected to the programmable matrix switch array. Each modular component card includes a predefined set of electronic components. The system comprises a configuration module configured to track the electronic components mounted on the modular component cards and connections with ports of the programmable matrix switch array and in response generate a portlist. The system comprises a netlist defining a circuit design, including interconnections between components of the circuit design. The system comprises a programming module configured to interpret the netlist and the portlist and in response generate switch activation commands to selectively control the cross-point switches.

According to the illustrative embodiment, the cross-point switches are selectively activated by the programming module to configure a physical circuit corresponding to the netlist.

According to the illustrative embodiment, the programmable matrix switch array includes a set of portboards interconnected to form an expandable switching matrix.

According to the illustrative embodiment, the modular component cards are configured to interface with the programmable matrix switch array, allowing reconfiguration of circuits without manual wiring.

According to the illustrative embodiment, the portlist specifies component types, component values, instrument types and connection ports for each electronic component.

According to the illustrative embodiment, the system comprises one or more instrument modules configured to apply test signals, measure responses, and verify circuit behavior by interfacing with the programmable matrix switch array.

According to the illustrative embodiment, the configuration module updates the portlist in response to insertion or removal of the modular component cards and instrument modules.

According to the illustrative embodiment, the programming module generates a sequence of addresses, each address corresponding to a specific cross-point switch.

According to the illustrative embodiment, the programming module includes a microcontroller or an FPGA configured to manage activation and de-activation of the crosspoint switches.

According to another illustrative embodiment, a system comprises a programmable matrix switch array including a set of portboards interconnected to form an expandable switching matrix. Each portboard includes a plurality of cross-point switches arranged in a grid. The system comprises one or more modular component cards, each removably connected to the programmable matrix switch array. Each modular component card includes a predefined set of electronic components. The system comprises a configuration module configured to track the electronic components mounted on the modular component cards and connections with ports of the programmable matrix switch array and in response generate a portlist. The system comprises a programming module configured to receive a netlist and the portlist and in response generate switch activation commands to selectively control the cross-point switches to configure a physical circuit corresponding to the netlist.

In another illustrative embodiment, a method for dynamically configuring an electronic circuit using a programmable matrix switch array comprises: detecting one or more modular component cards removably connected to the programmable matrix switch array, each modular component card containing a predefined set of electronic components; identifying connections between the modular component cards, instrument modules and the programmable matrix switch array and in response generating a portlist indicating the component types, component values, instrument types and connection ports based on the identified connections; receiving a netlist defining a desired circuit configuration; interpreting the netlist and the portlist to determine which cross-point switches in the programmable matrix switch array need to be activated and generating switch activation commands corresponding to the determined cross-point switches; sending the switch activation commands to the programmable matrix switch array; and configuring the programmable matrix switch array by selectively activating the cross-point switches to establish the desired circuit configuration.

### BRIEF DESCRIPTION OF THE DRAWINGS

The novel features believed characteristic of the illustrative embodiments are set forth in the appended claims. The illustrative embodiments, however, as well as a preferred mode of use, further objectives and features thereof, will best be understood by reference to the following detailed description of an illustrative embodiment of the present disclosure when read in conjunction with the accompanying drawings, wherein:

FIG. 1 illustrates a system in accordance with an illustrative embodiment;

FIG. 2 illustrates a switch array according to an illustrative embodiment;

FIG. 3 illustrates component cards in accordance with an illustrative embodiment;

FIG. 4 illustrates how component cards are connected to a switch array;

FIG. 5 illustrates a system designed with a modular architecture;

FIG. 6 provides a perspective view of a hardware-centric architecture;

FIG. 7 is a flow chart of a process in accordance with an illustrative embodiment;

FIG. 8 illustrates three component cards each with different sets of components;

FIG. 9 illustrates two component cards connected to their respective portboards; and

FIG. 10 illustrates a portlist.

### DETAILED DESCRIPTION

The illustrative embodiments provide a programmable matrix switch array. The programmable matrix switch array functions as a programmable crossbar for interconnecting electronic components. By selectively enabling specific switch points within the array, designers can rapidly configure and instantiate different circuit topologies without physically rewiring components.

The illustrative embodiments provide a modular matrix architecture that addresses the limitations of existing solutions. By integrating modular component cards and an expandable matrix switch array, the illustrative embodiments support a greater number of components and interconnections. The modular matrix architecture significantly broadens the range of possible circuit configurations, allowing designers to develop complex electronic systems efficiently. Furthermore, the modular scalability of this approach ensures that the prototyping process remains efficient, even as circuit complexity increases.

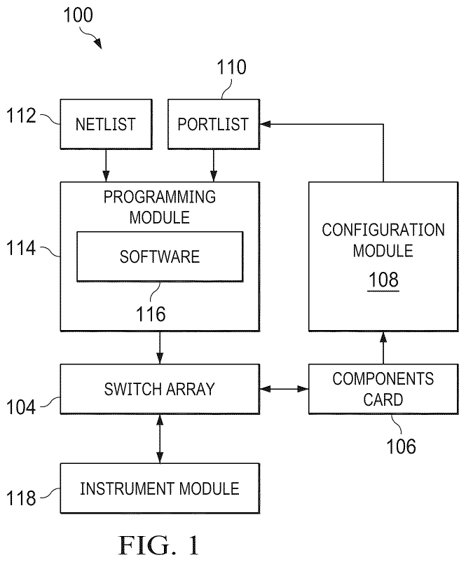

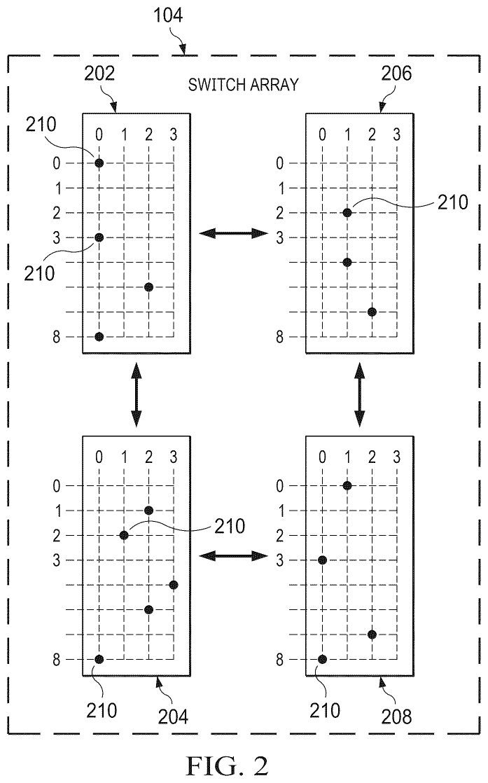

FIG. 1 illustrates system 100 in accordance with an illustrative embodiment. System 100 includes programmable matrix switch array 104. Switch array 104 includes one or more portboards which are described with reference to FIG. 2.

Switch array 104 functions as a programmable crossbar for interconnecting electronic components. Switch array 104 can be reconfigured to allow electronic components to be dynamically interconnected in various circuit configurations without requiring manual wiring. In an illustrative embodiment, switch array 104 is implemented as an analog switch array, which includes a grid of switches that can be controlled electronically to establish or break connections at designated cross-points.

System 100 includes one or more modular component cards 106. Component cards 106 are removable and interchangeable circuit boards that contain a predefined set of electronic components such as resistors, capacitors, inductors, diodes, transistors, or integrated circuits. One or more component cards can be attached to switch array 104 or they can be removed as necessary.

Although component cards 106 are described with reference to electronic components, micromechanical devices such as cantilevers, gears, semiconductor switches and other machines may be integrated into component cards 106. Also, electronic devices can be combined with mechanical devices and integrated into component cards 106 to create a mechatronics personal laboratory. The concepts disclosed herein may be applied to a wide range of scientific and engineering disciplines including but not limited to electronics, electromagnetics, mechanics, optics, fluidics, sensors, actuators and biotechnology.

Component cards 106 interface with switch array 104, allowing users to dynamically configure circuits without physically rewiring components. The components can be mounted in a standardized layout and may include standardized electrical contacts (e.g., edge connectors, pin headers, or PCB pads), ensuring interfacing with switch array 104.

System 100 includes configuration module 108. In an illustrative embodiment, configuration module 108 is implemented as a computer program which tracks the physical configuration of the hardware (e.g., component cards 106). When a component card is connected to switch array 104, configuration module 108 tracks electronic components such as resistors, capacitors, inductors, diodes, transistors, or integrated circuits which are contained in the component card. Configuration module 108 tracks port location, type, and value of components on component Cards 106. Also, configuration module 108 tracks any changes to the physical configuration of the component cards.

Based on the configuration of component cards 106, configuration module 108 generates portlist 110. In an illustrative embodiment, portlist 110 provides various information such as, for example, component types, component values and connection ports. For example, portlist 110 may indicate resistor R1 is connected to ports 1 and 2 of switch array 104, capacitor C1 is connected to ports 2 and 0 (ground) of switch array 104, and AC signal source V1 is connected to ports 1 and 0 (ground) of switch array 104. In other embodiments, interconnection flexibility is achieved when each component is assigned to an unshared (unique) port. For example, R1 can be connected to ports 1 and 2 of switch array 104, capacitor C1 can connected to ports 3 and 4 of switch array 104, and AC signal source V1 can be connected to ports 5 and 6 of switch array 104.

System 100 includes netlist 112 which is a textual representation of a circuit. For example, a designer may intend to analyze the behavior or performance of a particular electronic circuit. The designer can configure the electronic circuit using electronic design and analysis (EDA) tools, such as SPICE (Simulation Program with Integrated Circuit Emphasis). The designer can generate netlist 112 using EDA tools. Netlist 112 defines the components of the electronic circuit and the interconnections of the components.

For example, the designer may intend to analyze the behavior of an RC low-pass filter which includes a resistor R1 (1 kΩ), a capacitor C1 (0.1 μF) and an input voltage source V1 (AC signal). The RC-low-pass filter can be represented by the following netlist:
*RC Low-Pass Filter
V1 1 0 AC 1 SIN(0 1 1 k); [Explanation: AC voltage source between node 1 and ground with 1V peak and 1 kHz sine wave]
R1 1 2 1 k; [Explanation: Resistor between node 1 and node 2 (1 kΩ)]
C1 2 0 0.1 u; [Explanation: Capacitor between node 2 and ground (0.1 μF)]
. ac dec 10 10 100 k; [Explanation: Frequency sweep analysis from 10 Hz to 100 kHz]
. end;
End of the netlist

System 100 includes programming module 114 designed to interpret netlist 112 and portlist 110, and based on the interpretation, configure switch array 104. Programming module 114 sends commands to activate specific switches of the cross-point switch matrix on switch array 104 to interconnect components of component cards 106.

In an illustrative embodiment, programming module 114 includes programming software 116 which generates a sequence of 12-bit addresses. Programming module 114 decodes each 12-bit address to determine which specific cross-point switch to turn on and sends the activation command to switch array 104, enabling the switch in the matrix.

In an example embodiment, programming module 114 includes a microcontroller or a field programmable gate array (FPGA), which selectively activates the cross-point switches based on decoded addresses. The microcontroller or FPGA processes the incoming address instructions from software 116, manages timing sequences, and executes control over the switch activation process, ensuring that the intended circuit configuration is established.

Once programming module 114 has activated the required cross-point switches in switch array 104, system 100 is ready for testing. At this stage, instrument module 118 (e.g., oscilloscopes, measurement and test equipment), signal generators, and power supplies are connected to switch array 104 to apply test signals, measure responses, and verify the circuit behavior. The switch array 104 thus serves as the central hub where test instruments interface with the circuit under test.

In some example embodiments, one or more instrument modules are interconnected to system 100 like component cards 108 and are part of the overall circuit. For example, if an oscilloscope is connected to ports 7 and 8 of switch array 104, the oscilloscope will be listed on portlist 110. The oscilloscope will also be listed in netlist 112 including to which nodes it should be connected.

FIG. 2 illustrates switch array 104 according to an illustrative embodiment. In this example, switch array 104 includes four portboards: 202, 204, 206, and 208. Each portboard includes a grid of switches that can be controlled electronically to establish or break connections at designated cross-points to interconnect components on component cards 106. In another embodiment, switch array 104 may include more or fewer number of portboards.

Each portboard comprises X lines (horizontal conducting lines) and Y lines (vertical conducting lines), forming a crossbar or matrix structure. The X lines provide ports for component and instrument connections. At the intersections of X and Y lines are cross-point switches. The crosspoint switches can be turned on or off to control the electrical connections within a circuit.

In FIG. 2, dark circles 210 on the portboards indicate cross-point switches that have been turned on, establishing electrical connections between the corresponding X and Y lines. By selectively activating the cross-point switches, components on component cards 106 can be interconnected to configure a circuit. When a cross-point switch is turned on, the corresponding X and Y lines are electrically connected, enabling signal transmission between the connected components. Conversely, when a cross-point switch is turned off, the corresponding X and Y lines remain disconnected, preventing electrical continuity at that intersection. The activated crosspoint switches allow signals or power to flow through specific paths, forming the desired circuit configuration.

In an illustrative embodiment, programming module 114 receives instructions from software program 116 that contains information about which switches need to be turned-on and details about the timing sequence to execute the programming. An addressing scheme is used to identify each of the cross-point switches within switch array 104. In one embodiment, the addressing scheme comprises a 12-bit address used to target a port and a Y line (vertical conducting line) corresponding to a cross-point. A total of eight bits are used to address each port. Two of the eight bits are used to select a portboard, and six bits are used to address ports within each portboard, thus providing a total of 256 physical ports available for components. The remaining 4 bits are used to address sixteen Y lines.

As illustrated in FIG. 2, each portboard with 8 ports can be interconnected to form an expanded system with 16 ports and 8 Y lines. This expanded system allows different component cards to be attached to switch array 104 increasing circuit complexity and enhancing testing capabilities. In other example embodiments, switch array 104 can be configured with more or fewer X lines and Y lines. For example, a switch array can include eight interconnected portboards to provide 64 ports (X lines) and 16 nodes (Y lines).

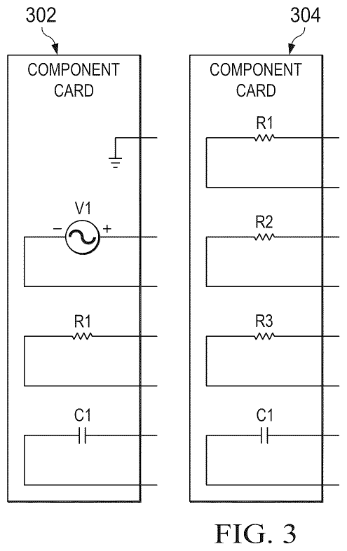

FIG. 3 illustrates example component cards 302 and 304 in accordance with an illustrative embodiment. Component card 302 includes ground (reference potential), signal source V1, resistor R1 and capacitor C1. Component card 304 includes resistor R1, resistor R2, resistor R3, and capacitor C1. Component cards may contain different or other electrical components such as diodes, transistors, inductors and integrated circuits. Although the component cards are described with reference to electronic components, micromechanical devices such as cantilevers, gears, semiconductor switches and other machines may be integrated into the component cards. Also, electronic devices can be combined with mechanical devices and integrated into component cards 106 to create a create a mechatronics personal laboratory.

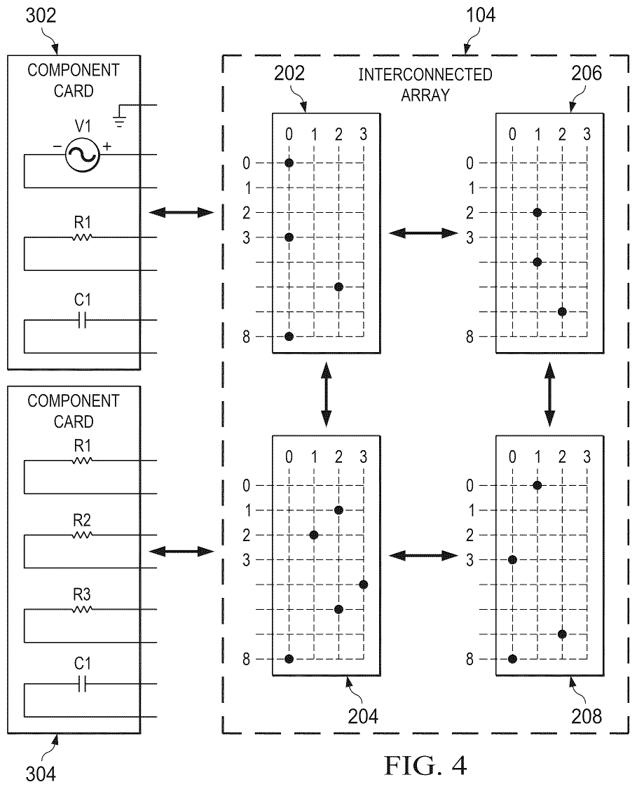

FIG. 4 illustrates how component cards 302 and 304 are connected to switch array 104. In this example, portboards 202, 204, 206, and 208 are cascaded to form the matrix switch array, enabling connections with component cards 302 and 304. The corresponding X and Y lines of the four portboards are interconnected to facilitate signal routing between components.

In component card 302: reference potential (ground) is connected to port 0 of portboard 202, V1 is connected to ports 2 and 3 of portboard 202, R1 is connected to ports 4 and 5 of portboard 202, and C1 is connected to ports 6 and 7 of portboard 202. As shown in this example, port 2 of portboard 202 is not used.

In component card 304: R1 is connected to ports 0 and 1 of portboard 204, R2 is connected to ports 2 and 3 of portboard 204, R3 is connected to ports 5 and 6 of portboard 204 and C1 is connected to ports 6 and 7 of portboard 204.

After connecting component boards 302 and 304 to the portboards, selected crosspoint switches on the four portboards are turned on, establishing the necessary electrical connections to complete the circuit configuration. In FIG. 4, the dark circles on the portboards indicate the crosspoint switches that have been turned on, signifying active electrical connections between the corresponding X and Y lines.

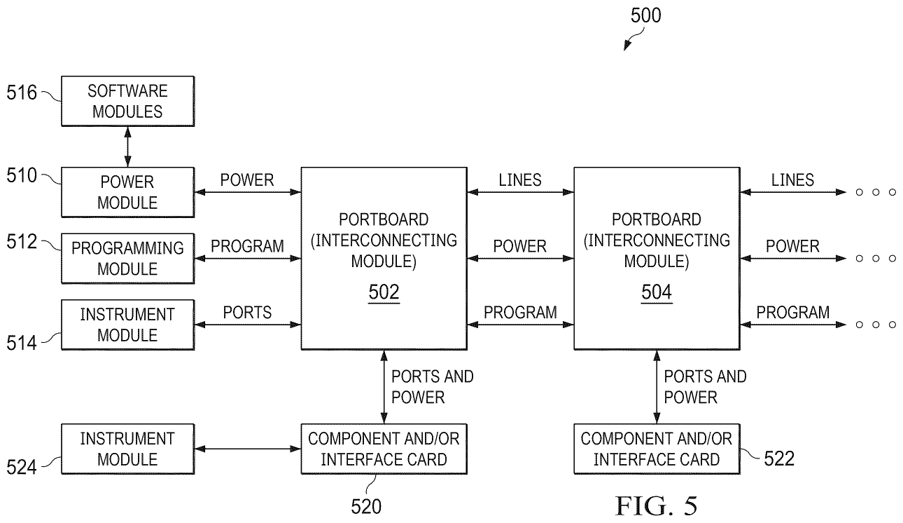

FIG. 5 illustrates system 500, which is designed with a modular architecture that enables various modules and components to be interconnected seamlessly.

System 500 includes portboards 502 and 504, which are interconnected to create an expanded system. These portboards are linked through dedicated ports, allowing the transfer of signals, power, and program instructions between them.

Additionally, power module 510, programming module 512, and instrument module 514 are connected to portboard 502 via designated ports. Programming module 512 receives programming instructions from software 516, ensuring the proper configuration of a circuit.

To enable circuit implementation, component cards 520 and 522 are connected to their respective portboards 502 and 504. Furthermore, instrument module 524 is directly connected to component card 520, demonstrating that instrument modules can either be connected directly to a portboard or to a component card depending on system requirements.

The modular nature of system 500 allows for scalability by integrating additional portboards, which in turn enables the connection of more component cards, expanding the system's capacity for circuit design and testing.

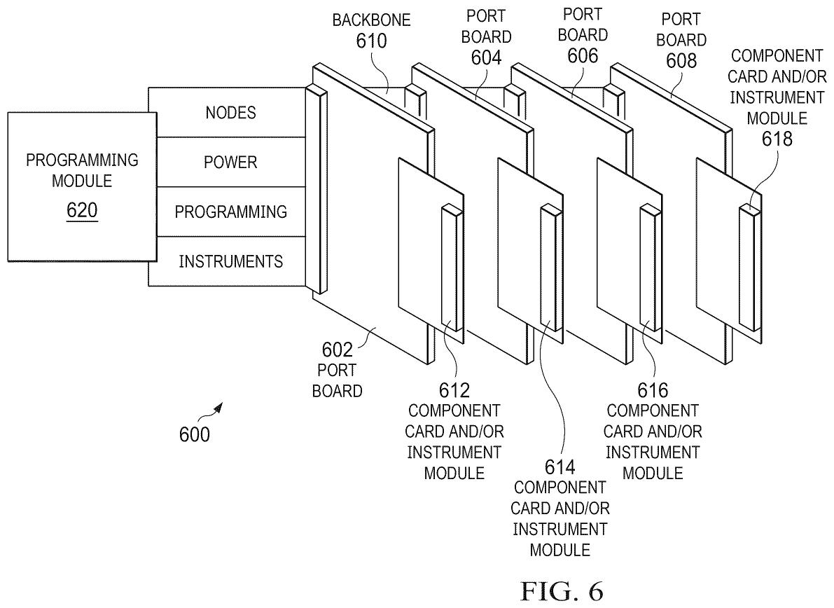

FIG. 6 provides a perspective view of hardware-centric architecture 600 in accordance with an illustrative embodiment. This architecture comprises four portboards 602, 604, 606, and 608, which are interconnected via backbone 610. Each portboard functions as a cross-point switch array, enabling the interconnection of components across four component cards and/or instrument modules 612, 614, 616, and 618.

Programming module 620 is responsible for sending commands to activate specific cross-point switches on the portboards, thereby establishing electrical connections between components on the component cards. Programming module operates in conjunction with programming software, which generates a sequence of addresses corresponding to specific cross-point switches.

To implement these connections, programming module 620 decodes each address to determine which cross-point switch needs to be turned on, then transmits the necessary activation command to the portboards, thereby enabling the selected switches in the matrix.

In an example embodiment, programming module 620 includes a microcontroller or a field programmable gate array (FPGA), which selectively activates the cross-point switches based on decoded addresses. The microcontroller or FPGA processes the incoming address instructions, manages timing sequences, and executes control over the switch activation process, ensuring that the intended circuit configuration is established.

In some embodiments, configuration module 108 and software 116 (illustrated in FIG. 1) include computer-readable program instructions to cause a series of operational steps to be performed by one or more processors and thereby effect a computer-implemented method, such that the instructions thus executed will instantiate the methods specified in flowcharts and/or narrative descriptions of computer-implemented methods included in this document. These computer-readable program instructions are stored in various types of computer-readable storage media, such as a cache and the other storage media. The program instructions and associated data are accessed by one or more processors to control and direct performance of the inventive methods.

In some embodiments, configuration module 108, programming module 114 and software 116 may be implemented as a single module which includes computer-readable program instructions to cause a series of operational steps to be performed by one or more processors.

A computer program product embodiment is a term used in the present disclosure to describe any set of one or more storage media collectively included in a set of one or more storage devices that collectively include machine readable code corresponding to instructions and/or data for performing computer operations. A storage device is any tangible device that can retain and store instructions for use by a computer processor.

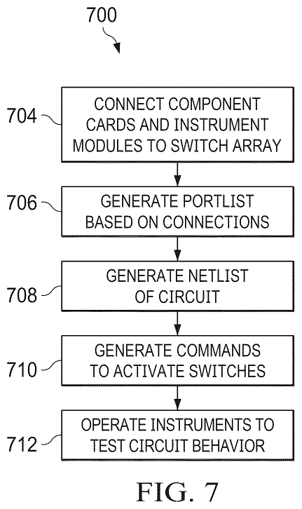

FIG. 7 is a flow chart of process 700 in accordance with an illustrative embodiment. In block 704, component cards (e.g., component cards 106) and instrument modules are connected to a switch array (e.g., switch array 104). In block 706, a portlist (e.g., portlist 110) is generated based on how components on the component cards and instrument modules are connected to the switch array. The configuration module can update the portlist in response to insertion or removal of modular component cards and instrument modules.

In block 708, a netlist (e.g., netlist 112) which is a textual representation of a circuit is generated. In block 710, based on an analysis of the portlist and the netlist, a series of commands are generated to activate specific cross-point switches on the switch array, thereby establishing electrical connections between components on the component cards. In block 712, instruments such as signal sources, oscilloscopes and other test and measurement equipment are operated to test the behavior and performance of the circuit.

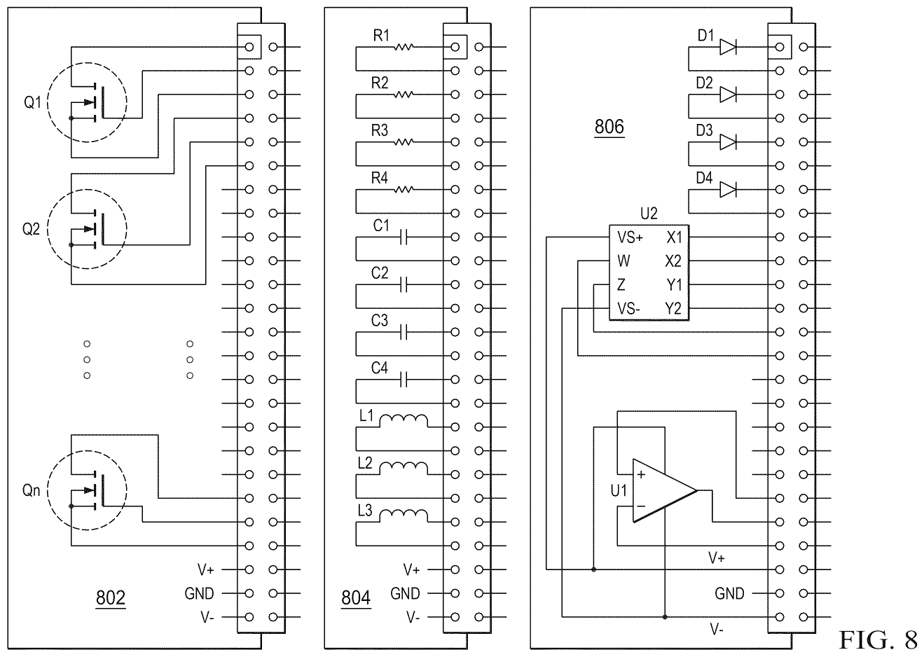

FIG. 8 illustrates three example component cards 802, 804 and 805 each with different sets of components. In this example, component card 802 includes transistors, component card 804 includes resistors, capacitors and inductors, and component card 806 includes diodes and other integrated circuits. The component cards can also provide power to integrated circuits and other active devices.

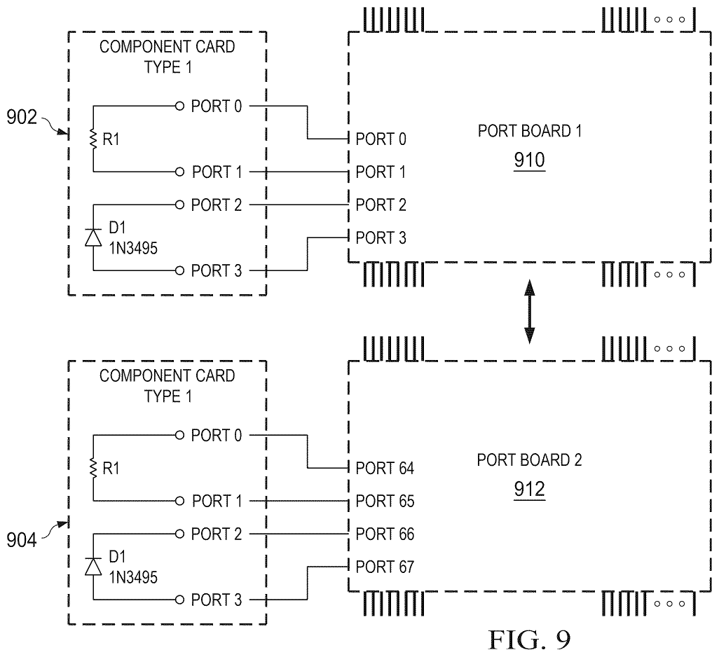

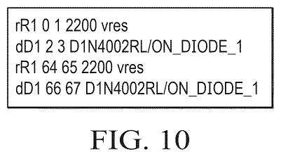

FIG. 9 illustrates two example component cards 902 and 904 connected to their respective portboards 910 and 912. Portboards 910 and 912 are interconnected. FIG. 10 illustrates portlist 1000 based on the interconnection of component cards 902 and 904 and portboards 910 and 912.

In some embodiments, system 100 (shown in FIG. 1) is implemented as a modular portable system. For example, switch array 104, component cards 106, configuration module 108 and programming module 108 are configured as a portable system that can be connected to a computer (e.g., desktop computer, lap-top computer). One or more instrument modules can be connected to the portable system. The computer can be equipped with an EDA tool which provides a netlist to the portable system.

As used herein, “a number of,” when used with reference to items, means one or more items. For example, “a number of different types of networks” is one or more different types of networks.

Further, the phrase “at least one of,” when used with a list of items, means different combinations of one or more of the listed items can be used, and only one of each item in the list may be needed. In other words, “at least one of” means any combination of items and number of items may be used from the list, but not all of the items in the list are required. The item can be a particular object, a thing, or a category.

For example, without limitation, “at least one of item A, item B, or item C” may include item A, item A and item B, or item B. This example also may include item A, item B, and item C or item B and item C. Of course, any combinations of these items can be present. In some illustrative examples, “at least one of” can be, for example, without limitation, two of item A; one of item B; and ten of item C; four of item B and seven of item C; or other suitable combinations.

In some alternative implementations of an illustrative embodiment, the function or functions noted in the blocks may occur out of the order noted in the figures. For example, in some cases, two blocks shown in succession may be performed substantially concurrently, or the blocks may sometimes be performed in the reverse order, depending upon the functionality involved. Also, other blocks may be added in addition to the illustrated blocks in a flowchart or block diagram.

The different illustrative examples describe components that perform actions or operations. In an illustrative embodiment, a component may be configured to perform the action or operation described. For example, the component may have a configuration or design for a structure that provides the component an ability to perform the action or operation that is described in the illustrative examples as being performed by the component.

Many modifications and variations will be apparent to those of ordinary skill in the art. Further, different illustrative embodiments may provide different features as compared to other illustrative embodiments. The embodiment or embodiments selected are chosen and described in order to best explain the principles of the embodiments, the practical application, and to enable others of ordinary skill in the art to understand the disclosure for various embodiments with various modifications as are suited to the particular use contemplated.

What is claimed is:

1. A system comprising:
a programmable matrix switch array including a plurality of cross-point switches arranged in a grid, wherein each cross-point switch is selectively configurable to establish or break electrical connections at designated intersections of conducting lines;
one or more modular component cards, each removably connected to the programmable matrix switch array, wherein each modular component card includes a predefined set of electronic components;
a configuration module configured to track the electronic components mounted on the modular component cards and connections with ports of the programmable matrix switch array and in response generate a portlist;
a netlist defining a circuit design, including interconnections between components of the circuit design; and
a programming module configured to interpret the netlist and the portlist and in response generate switch activation commands to selectively control the cross-point switches.

2. The system of claim 1, wherein the cross-point switches are selectively activated by the programming module to configure a physical circuit corresponding to the netlist.

3. The system of claim 1, wherein the programmable matrix switch array includes a set of portboards interconnected to form an expandable switching matrix.

4. The system of claim 1, wherein the modular component cards are configured to interface with the programmable matrix switch array, allowing reconfiguration of circuits without manual wiring.

5. The system of claim 1, wherein the portlist specifies component types, component values, instrument types and connection ports for each electronic component.

6. The system of claim 1, further comprising one or more instrument modules configured to apply test signals, measure responses, and verify circuit behavior by interfacing with the programmable matrix switch array.

7. The system of claim 1, wherein the configuration module updates the portlist in response to insertion or removal of modular component cards and instrument modules.

8. The system of claim 1, wherein the programming module generates a sequence of addresses, each address corresponding to a specific cross-point switch.

9. The system of claim 1, wherein the programming module includes a microcontroller or an FPGA configured to manage activation and de-activation of the crosspoint switches.

10. A system comprising:
a programmable matrix switch array including a set of portboards interconnected to form an expandable switching matrix, wherein each portboard including a plurality of cross-point switches arranged in a grid;
one or more modular component cards, each removably connected to the programmable matrix switch array, wherein each modular component card includes a predefined set of electronic components;
a configuration module configured to track the electronic components mounted on the modular component cards and connections with ports of the programmable matrix switch array and in response generate a portlist; and
a programming module configured to receive a netlist and the portlist and in response generate switch activation commands to selectively control the cross-point switches to configure a physical circuit corresponding to the netlist.

11. The system of claim 10, wherein the portlist specifies component types, component values, instrument types and connection ports for each electronic component.

12. The system of claim 10, wherein the netlist defines a circuit design, including interconnections between components and instruments of the circuit design.

13. The system of claim 10, wherein the activation commands selectively control the cross-point switches to establish or break electrical connections at designated intersections of conducting lines.

14. The system of claim 10, wherein the programming module is configured to decode a sequence of addresses and selectively activate specific cross-point switches in the switch array to implement the physical circuit corresponding to the netlist.

15. The system of claim 10, further comprising an instrument module configured to interface with the switch array to provide test signals and measure circuit performance.

16. The system of claim 10, wherein the modular component cards are configured to interface with the programmable matrix switch array, allowing reconfiguration of circuits without manual wiring.

17. The system of claim 10, further comprising one or more instrument modules configured to apply test signals, measure responses, and verify circuit behavior by interfacing with the programmable matrix switch array.

18. The system of claim 10, wherein the configuration module updates the portlist in response to insertion or removal of modular component cards and instrument modules.

19. The system of claim 10, wherein the programming module includes a microcontroller or an FPGA configured to manage activation and de-activation of the crosspoint switches.

20. A method for dynamically configuring an electronic circuit using a programmable matrix switch array, the method comprising:
detecting one or more modular component cards removably connected to the programmable matrix switch array, each modular component card containing a predefined set of electronic components;
identifying connections between the modular component cards, instrument modules and the programmable matrix switch array and in response generating a portlist indicating the component types, component values, instrument types and connection ports based on the identified connections;
receiving a netlist defining a desired circuit configuration;
interpreting the netlist and the portlist to determine which cross-point switches in the programmable matrix switch array need to be activated and generating switch activation commands corresponding to the determined cross-point switches;
sending the switch activation commands to the programmable matrix switch array; and
configuring the programmable matrix switch array by selectively activating the cross-point switches to establish the desired circuit configuration.

21. The method of claim 20, further comprising applying test signals to the configured circuit using the instrument modules.

22. The method of claim 20, further comprising updating the portlist in response to the removal or insertion of modular component cards and instrument modules.
